(19) United States
(12) Patent Application Publication
(10) Pub. No.: US 2014/0130863 A1
(43) Pub. Date: May 15, 2014

(54) PHOTOVOLTAIC MODULE

(71) Applicant: SANYO Electric Co., Ltd., Osaka (JP)

(72) Inventor: Atsushi SAITA, Hyogo (JP)

(73) Assignee: SANYO Electric Co., Ltd., Osaka (JP)

(21) Appl. No.: 14/159,976

(22) Filed: Jan. 21, 2014

Related U.S. Application Data
(63) Continuation of application No. PCT/JP2012/057126, filed on Mar. 21, 2012.

(30) Foreign Application Priority Data
Jul. 28, 2011 (JP) 2011-165668

(51) Int. Cl. H01L 31/048

(52) U.S. Cl. CPC H01L 31/048
USPC 136/256

(57) ABSTRACT

A photovoltaic module comprises a plurality of photovoltaic elements connected by a wiring member; a bus bar portion provided on the light-receiving surface of each of the photovoltaic elements; and an adhesive having a first adhesion section and a second adhesion section, the adhesive being provided on the bus bar portion to connect the bus bar portion and the wiring member to each other. The first adhesion section has a higher electrical conductivity than that of the second adhesion section, and the second adhesion section has a higher translucency than that of the first adhesion section.

### CROSS-REFERENCE TO RELATED APPLICATION

The present application is a continuation under 35 U.S.C. §120 of PCT/JP2012/057126, filed Mar. 21, 2012, which is incorporated herein by reference and which claimed priority to Japanese. Patent Application No. 2011-165668 filed Jul. 28, 2011. The present application likewise claims priority under 35 U.S.C. §119 to Japanese Patent Application No. 2011-165668 filed Jul. 28, 2011, the entire content of which is also incorporated herein by reference.

### TECHNICAL FIELD

The present invention relates to a photovoltaic module.

### BACKGROUND ART

Solar cell systems and other systems have attracted much attention as an environmentally-friendly energy source. As an example, Patent Document 1 discloses a photovoltaic module including a photovoltaic element, a light-receiving surface electrode provided on a light-receiving surface of the photovoltaic element, and a rear surface electrode provided on a rear surface of the photovoltaic element. In this photovoltaic module, each of the light-receiving surface electrode and the rear surface electrode includes a plurality of finger portions and a bus bar portion electrically connected to the plurality of finger portions.

### PRIOR ART DOCUMENT

### Patent Document

Patent Document 1: JP 2009-290234 A

### DISCLOSURE OF THE INVENTION

### Technical Problems

A photovoltaic module includes a plurality of photovoltaic elements. In order to connect these photovoltaic elements electrically with each other, a wiring member is used. The wiring member is bonded to a bus bar portion of the photovoltaic element by using an adhesive, with conductivity of the wiring member being maintained. At this time, the adhesive may overflow from the outer peripheral portion of the wiring member and may be exposed. If the adhesive is formed of a material having low translucency, the sunlight is blocked by the exposed portion of the adhesive, which adversely affects the photovoltaic efficiency.

### Solution to Problems

The photovoltaic module according to the present invention includes a photovoltaic element including an electrode portion on a light-receiving surface thereof; a wiring member; and an adhesive layer provided between the wiring member and the electrode portion, the adhesive layer including a first adhesion section and a second adhesion section, and the first adhesion section has conductivity that is higher than conductivity of the second adhesion section, and the second adhesion section has translucency that is higher than translucency of the first adhesion section.

### Advantageous Effects of Invention

According to the present invention, it is possible to enhance the properties of a photovoltaic module.

### BRIEF DESCRIPTION OF THE DRAWINGS

FIG. 1 Cross sectional view of a photovoltaic module according to an embodiment of the present invention.

FIG. 2 Plan view of a photovoltaic element on the light-receiving surface side according to the embodiment of the present invention.

FIG. 3 Plan view of a photovoltaic element on the rear surface side according to the embodiment of the present invention.

FIG. 4 Cross sectional view taken along line A-A in FIG. 2.

FIG. 5 Flow chart illustrating procedure of a method of manufacturing a photovoltaic element according to the embodiment of the present invention.

FIG. 6 Flow chart illustrating procedure of a method of manufacturing a photovoltaic module according to the embodiment of the present invention.

FIG. 7 View corresponding to an enlarged view of a portion enclosed by a chain double-dashed line B in FIG. 2, and illustrating a state before a wiring member is connected to a bus bar portion.

FIG. 8 View corresponding to a cross sectional view taken along line C-C in FIG. 7 and illustrating a state before a wiring member is connected to a bus bar portion.

FIG. 9 View corresponding to a cross sectional view taken along line C-C in FIG. 7 and illustrating a state before a wiring member is connected to a bus bar portion.

FIG. 10 Flow chart illustrating procedure for connecting a wiring member and a bus bar portion with the use of an adhesive according to the embodiment of the present invention.

FIG. 11 View corresponding to a cross sectional view taken along line C-C in FIG. 7 and illustrating a state before a wiring member is connected to a bus bar portion.

FIG. 12 View corresponding to a cross sectional view taken along line C-C in FIG. 7 and illustrating a state before a wiring member is connected to a bus bar portion.

FIG. 13 View illustrating a modification example concerning application of a first adhesion section and a second adhesion section according to the embodiment of the present invention.

FIG. 14 View illustrating a modification example concerning application of a first adhesion section and a second adhesion section according to the embodiment of the present invention.

### BEST MODE FOR CARRYING OUT THE INVENTION

An embodiment of the present invention will be described in detail with reference to the drawings. In the following description, similar elements are denoted by the same numeral reference in all the drawings, and will not be described repeatedly. In the description, numeral references that have been described before may be used as required.

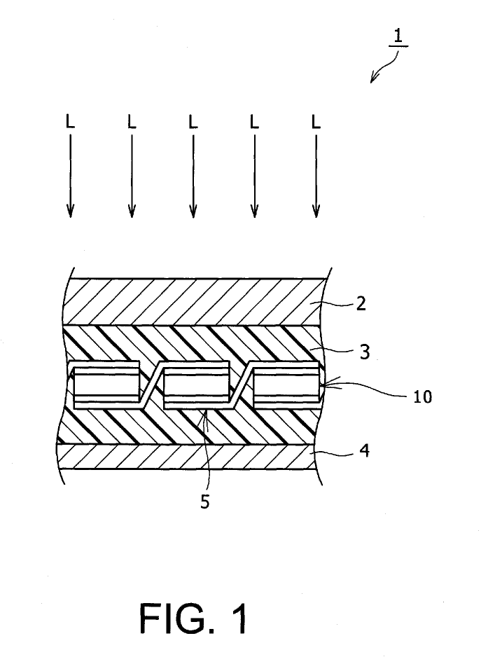

FIG. 1 is a cross sectional view of a photovoltaic module 1. The photovoltaic module 1 includes a plurality of photovoltaic elements 10, a plurality of wiring members 5, a sealing member 3, a first protective member 2, and a second protective member 4. In this example, as illustrated in FIG. 1, light such as sunlight enters the photovoltaic module 1 along a direction of an arrow L.

The plurality of photovoltaic elements 10 are arranged in alignment. The wiring members 5 electrically connect adjacent photovoltaic elements 10. The wiring member 5 is formed of a conductive material, such as a metal. With this structure, the plurality of photovoltaic elements 10 are electrically connected in series or in parallel with each other.

The first protective member 2 is disposed on the light-receiving surface side of the photovoltaic elements 10. The first protective member 2 can be formed by using a member having transparency such as glass, a transparent resin, or other materials, for example.

The second protective member 4 is disposed on the rear-surface side of the photovoltaic elements 10. The second protective member 4 can be formed by using a weatherable member such as a resin film, a resin film having a metal foil such as aluminum foil interposed therein, and other materials, for example.

The sealing member 3 fills a space between the photovoltaic element 10 and the first protective member 2, a space between the photovoltaic member 10 and the second protective member 4, and a space between the adjacent photovoltaic elements 10. The plurality of photovoltaic elements 10 are sealed with this sealing member 3. The sealing member 3 can be formed by using a resin such as ethylene vinyl acetate copolymer (EVA) and polyvinyl butyral (PVB), for example.

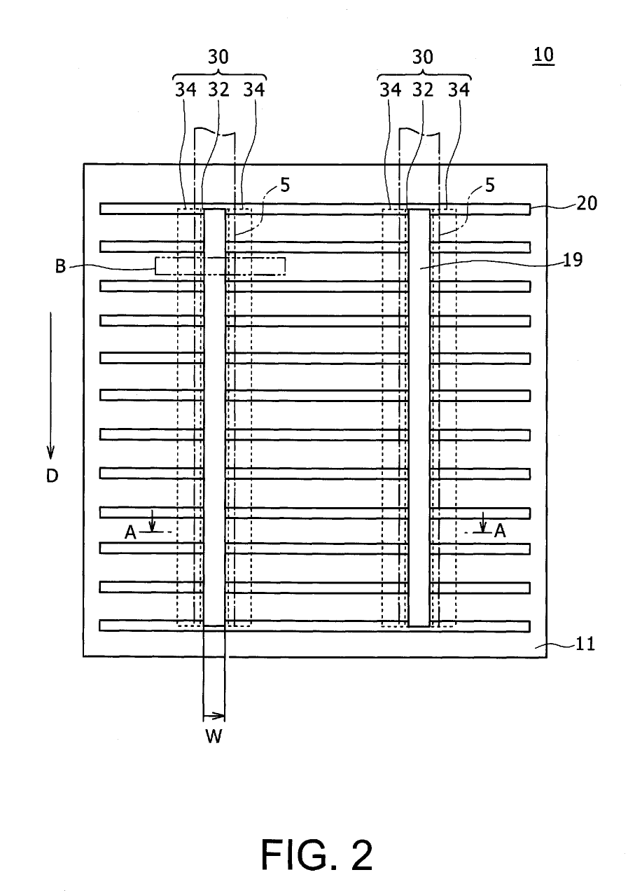

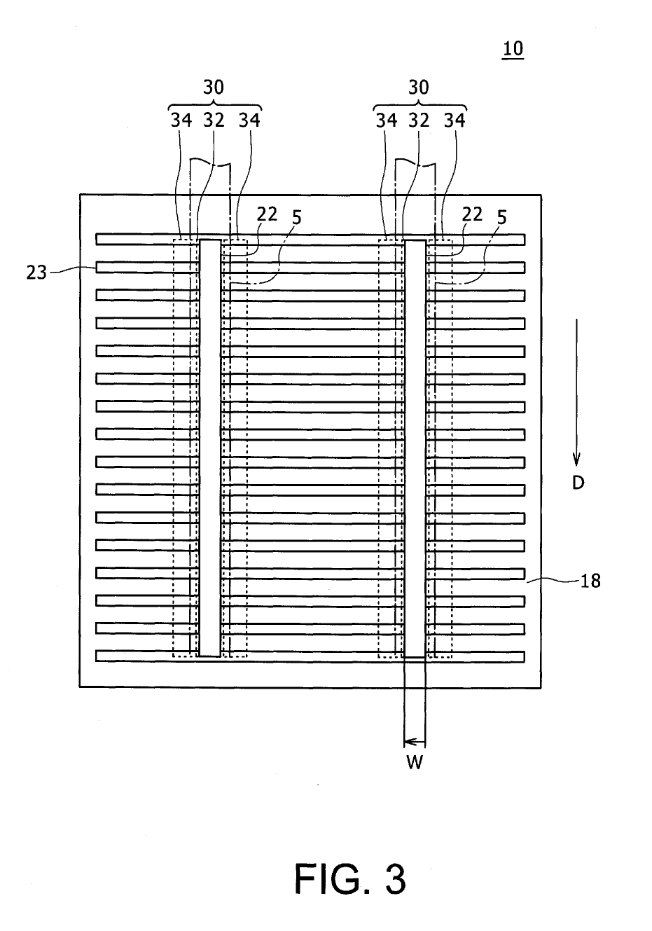

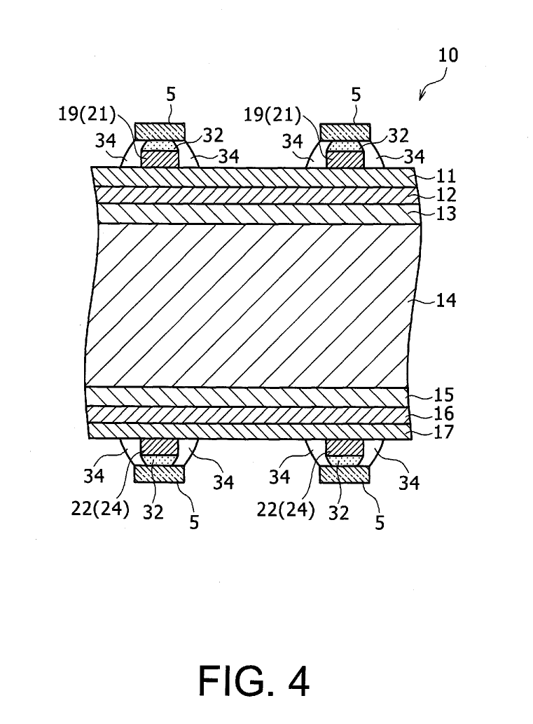

FIG. 2 is a plan view of the photovoltaic element 10 on the light-receiving surface side, and FIG. 3 is a plan view of the photovoltaic element 10 on the rear surface side. FIG. 4 is a cross sectional view taken along line A-A in FIG. 2. The “light-receiving surface” refers to a surface which light such as sunlight mainly enters and the “rear surface” refers to a surface which is opposite to the light-receiving surface.

The photovoltaic element 10 includes, from the light entering side, a transparent conductive layer 11, an n-type amorphous silicon layer 12, an i-type amorphous silicon layer 13, an n-type single-crystal silicon substrate 14, an i-type amorphous silicon layer 15, a p-type amorphous silicon layer 16, and a transparent conductive layer 17. Further, the photovoltaic element 10 includes, on the light-receiving surface side thereof, a collection electrode 21 including a plurality of finger electrode portions 20 and a plurality of bus bar electrode portions 19. The photovoltaic element 10 also includes, on the rear surface side thereof, a collection electrode 24 including a plurality of finger electrode portions 23 and a plurality of bus bar electrode portions 22. It is preferable that the collection electrode 21 has a smaller area than the collection electrode 24 on the rear surface side in order to reduce the light shielding loss.

An adhesion layer 30 connects between the bus bar portion 19 and the wiring member 5 and between the bus bar portion 22 and the wiring member 5. The adhesion layer 30 includes a first adhesion section 32 and a second adhesion section 34. For the first adhesion section 32 and the second adhesion section 34, a thermosetting adhesive containing an adhesive resin material, such as an epoxy resin, an acrylic resin, a urethane resin, and other materials, can be used, for example. In this example, as the first adhesion section 32 and the second adhesion section 34, a thermosetting adhesive containing a resin having translucency such as an epoxy resin is used. The first adhesion section 32 and the second adhesion section 34 differ from each other in that the first adhesion section 32 contains a conductive filler including a conductive material (a low-resistant metal such as Ni, Ag, Au, Cu or a solder material such as SnBi, SnAgCu) whereas the second adhesion section 34 does not contain a conductive filler including the conductive material as described above, or contains such a conductive filler in an amount which is smaller than that in the first adhesion section 32. Accordingly, the first adhesion section 32 has higher conductivity than that of the second adhesion section 34, and the second adhesion section 34 has higher translucency than that of the first adhesion section 32.

The n-type single-crystal silicon substrate 14 is an electric generation layer for generating carriers with light entering from the light-receiving surface. While in the present embodiment the n-type single-crystal silicon substrate 14 functions as the electric generation layer, the present invention is not limited to this example, and the electric generation layer can be a substrate formed of an n-type or p-type conductive crystalline semiconductor material. A polycrystalline silicon substrate, a gallium arsenide (GaAs) substrate, an indium phosphide (InP) substrate, for example, may be applied, in addition to a single-crystal silicon substrate.

The i-type amorphous silicon layer 13 is provided on the light-receiving surface of the n-type single-crystal silicon substrate 14 and is composed of amorphous silicon formed under the condition that the amorphous silicon contains no p-type impurities or no n-type impurities. The n-type amorphous silicon layer 12 is provided on the i-type amorphous silicon layer 13 and is composed of amorphous silicon in which n-type impurities are doped.

The transparent conductive layer 11 is formed on the n-type amorphous silicon layer 12. Preferably, the transparent conductive layer 11 is formed by including at least one of conductive metal oxides such as indium oxide (In₂O₃) containing dopant, zinc oxide (ZnO), tin oxide (SnO₂), and titanium oxide (TiO₂) which include dopant. In this example, it is assumed that the transparent conductive layer 11 is formed by using indium tin oxide (ITO).

In place of the n-type amorphous silicon layer 12, an n-type diffusion layer which is formed by thermal diffusion of n-type impurities at a high concentration in an n-type single-crystal silicon substrate may be used. In this case, it is not necessary to provide the i-type amorphous silicon layer 13 and the transparent conductive layer 11.

The finger portion 20 is an electrode member which is provided for collecting the carriers generated in the photovoltaic element 10. It is preferable to dispose the finger electrode portions 20 such that carriers can be collected evenly from within the plane of the photovoltaic element 10. Specifically, a plurality of finger portions 20 extending in a line shape are arranged in parallel over substantially the entire region of the surface of the transparent conductive layer 11 at predetermined intervals. The width of the finger portion 20 is determined as appropriate in accordance with the quantity of electric current flowing therethrough, the thickness of the finger portion 20, and other factors, and is 50 μm to 100 μm, for example. Further, the pitch of the finger portions 20 is preferably 1.5 mm to 3 mm, for example. The number of the finger portions 20 is made smaller than that of the finger portions 23 on the rear surface side, in order to reduce the light shielding loss.

The bus bar portion 19 is an electrode member which is provided for collecting the carriers collected in the finger portions 20. It is preferable to dispose the bus bar portions 19 so as to collect the carriers collected in the finger portion 20 as uniformly as possible. For example, a plurality of bus bar portions 19 may be provided at intervals. It is preferable to arrange the bus bar portions 19 in parallel to each other on the transparent conductive layer 11. The width of the bus bar portion 19 is determined as appropriate in accordance with the quantity of electric flowing therethrough, the thickness of the bus bar portion 19, and other factors, and is 0.5 mm to 3 mm, for example. In this example, it is assumed that the width of the bas bar portion 19 is greater than the width of the finger portion 20.

The bus portion 19 and the finger portion 20 can be formed by a conductive material, which is a metal such as Ag (gold), Cu (copper), Al (aluminum), Ti (titanium), Ni (nickel), and Cr (chromium), or an alloy containing one or more types of these metals, for example. The bus bar portion 19 and the finger portion 20 can be formed by using a conductive paste such as Ag paste, for example, or can be formed by other methods including evaporation and plating, for example. Here, the description will be given on the assumption that the bus bar portion 19 and the finger portion 20 are formed by using Ag.

The i-type amorphous silicon layer 15 is provided on the rear surface of the n-type single-crystal silicon substrate 14. The i-type amorphous silicon layer 15 is formed of amorphous silicon which is formed under the condition that the amorphous silicon contains no p-type impurities or no i-type impurities. The p-type amorphous silicon layer 16 is provided on the i-type amorphous silicon layer 15 and is formed of amorphous silicon in which p-type impurities are doped.

The transparent conductive layer 17 is formed on the p-type amorphous silicon layer 16. The transparent conductive layer 17 is formed by including a material which is similar to that of the transparent conductive layer 11. In this example, it is assumed that the transparent conductive layer 17 is formed by using indium tin oxide (ITO).

In place of the p-type amorphous silicon layer 16, a p-type diffusion layer which is formed by thermal diffusion of p-type impurities in an n-type single-crystal silicon substrate may be used. In this case, it is not necessary to provide the i-type amorphous silicon layer 15 and the transparent conductive layer 17.

The finger portion 23 is an electrode member which is provided for collecting the carriers generated in the photovoltaic element 10. Similar to the finger portions 20, a plurality of finger portions 23 extending in a line shape are arranged in parallel over substantially the entire region of the surface of the transparent conductive layer 17 at predetermined intervals. The width of the finger portion 23 is determined as appropriate in accordance with the quantity of electric current flowing therethrough, the thickness of the finger portion 23, and other factors, and is 50 μm to 100 μm, for example. Further, the pitch of the finger portions 23 is preferably 1.5 mm to 3 mm, for example. The bus bar portions 22 are also disposed in a manner similar to the bus bar portions 19. The width of the bus bar portion 22 is determined as appropriate in accordance with the quantity of electric current flowing therethrough, the thickness of the bus bar portion 22, and other factors, and is 0.5 mm to 3 mm, for example. In this example, it is assumed that the width of the bas bar portion 22 is greater than the width of the finger portion 23.

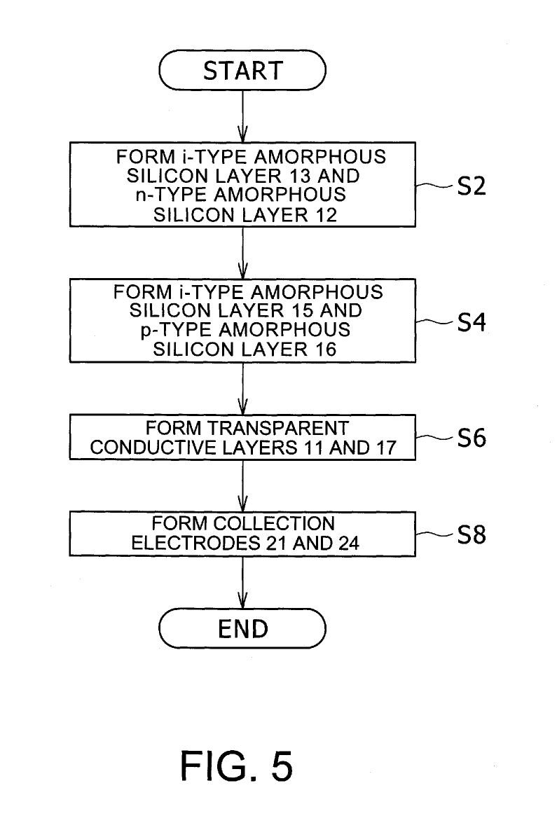

A method of manufacturing the photovoltaic element 10 will be described with reference to FIG. 5. FIG. 5 is a flow chart illustrating the procedure of a method of manufacturing the photovoltaic element 10.

First, the substrate 14 formed of n-type single-crystal silicon is cleaned, and then a texture structure is formed on the light-receiving surface and the rear surface thereof by etching and other methods. Subsequently, the substrate 14 is placed within a vacuum chamber, and the i-type amorphous silicon layer 13 is formed on the light-receiving surface of the substrate 14 by using a CVD method, and the n-type amorphous silicon layer 12 is formed on the i-type amorphous silicon layer 13 (S2). Next, with the use of the CVD method, the i-type amorphous silicon layer 15 is formed on the rear surface of the substrate 14, and the p-type amorphous silicon layer 16 is further formed on the i-type amorphous silicon layer 15 (S4). Thereafter, with the use of a vapor deposition method, the transparent conductive layer 11 and the transparent conductive layer 17, each of which is formed of ITO, are formed on the n-type amorphous silicon layer 12 and the p-type amorphous silicon layer 16, respectively (S6). Finally, with the use of a screen printing method, the collection electrode 21 and the collection electrode 24 are formed on the transparent conductive layer 11 and the transparent conductive layer 17, respectively (S8). As described above, with the steps from S2 through S8, a single photovoltaic element 10 can be manufactured.

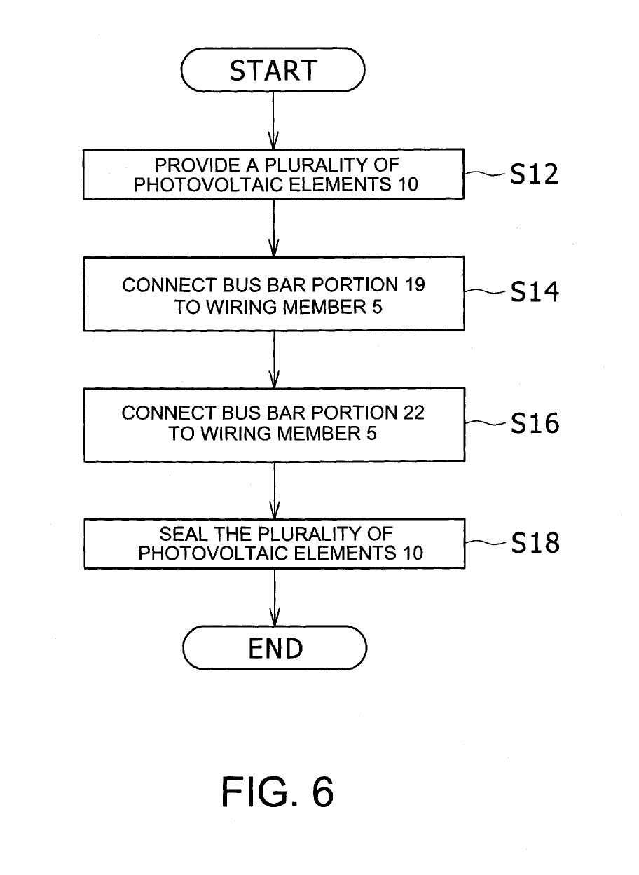

With reference to FIG. 6, a method for manufacturing the photovoltaic module 1 will be described. FIG. 6 is a flow chart illustrating the procedure for the method for manufacturing the photovoltaic module 1.

First, a plurality of photovoltaic elements 10 are provided (S12). Then, each bus bar portion 19 and each wiring member 5 are connected to each other with the adhesive layer 30, having been subjected to thermal compression bonding, being interposed therebetween (S14). Similar to the step S14, each bus bar portion 22 and each wiring member 5 are connected to each other with the adhesive layer 30 which has been thermal compression bonded being interposed therebetween (S16). With the completion of the step S16, a plurality of photovoltaic elements 10 are electrically connected. Finally, the plurality of photovoltaic elements 10 which are electrically connected by the wiring members 5 are stored between the first protective member 2 and the second protective member 4, and are then sealed by providing the sealing member 3 (18). As described above, with the steps from S12 through S18, it is possible to manufacture the photovoltaic module 1. Here, the step of connecting each bus bar portion 19 and each wiring member 5 (S14), and the step of connecting each bus bar portion 22 and each wiring member 5 (S16), may be performed simultaneously.

In the method of manufacturing the photovoltaic module 1 described above, the step S14 constitutes a characteristic of the present embodiment. Therefore, this step will be described in further detail below.

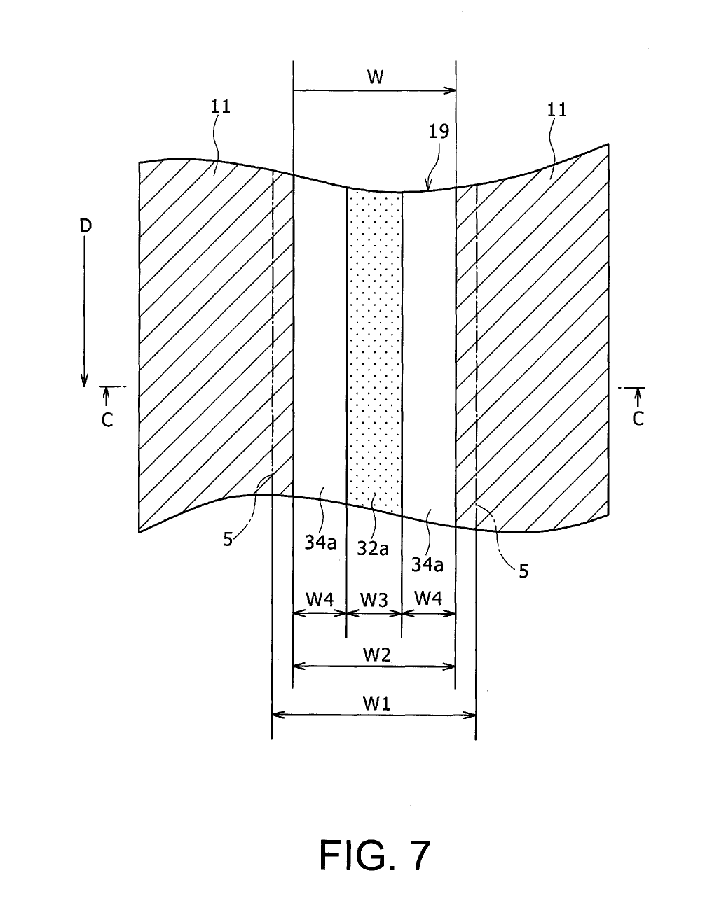

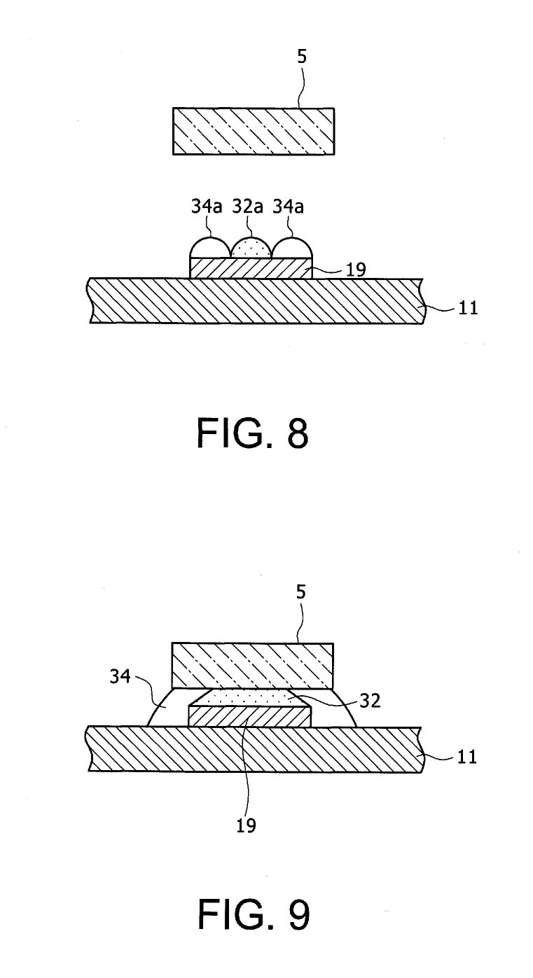

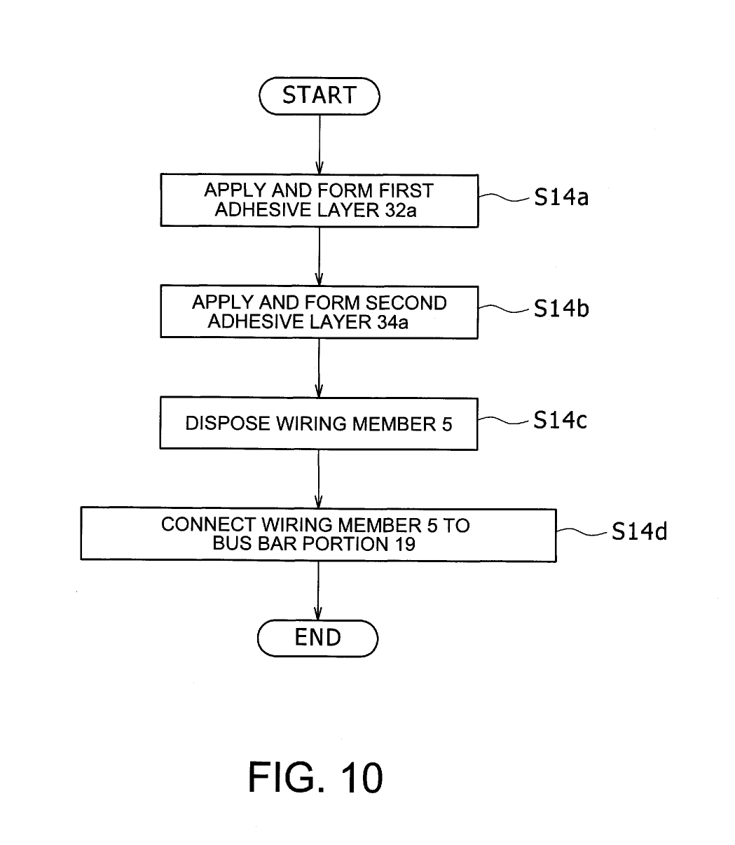

FIG. 7 is a view corresponding to an enlarged view of the portion enclosed by a chain double-dashed line B in FIG. 2, and illustrates a state before connecting the wiring member 5 to the bus bar portion 19. FIG. 8 is a view corresponding to a cross sectional view taken along line C-C in FIG. 7 and illustrates a state before connecting the wiring member 5 to the bus bar portion 19. FIG. 9 is a view corresponding to a cross sectional view taken along line C-C in FIG. 7 and illustrates a state after the wiring member 5 is connected to the bus bar portion 19. FIGS. 7 to 9 illustrate a positional relationship among the first adhesion section 32, the second adhesion section 34, the bus bar portion 19, and the wiring member 5. FIG. 10 is a flow chart illustrating the procedure for connecting the wiring member 5 and the bus bar portion 19 with the use of the adhesive layer 30. The direction of arrow D in FIG. 7 corresponds to the direction of arrow D in FIG. 2. Further, the direction of arrow W in FIG. 7 corresponds to the direction of arrow W in FIG. 2.

With reference to FIGS. 7 to 10, the step S14 will be described more specifically. First, as illustrated in FIG. 7, on the bus bar portion 19, an adhesive for the first adhesion section is applied to the center portion in the width direction (direction of arrow W) of the bus bar portion 19 along the longitudinal direction (direction of arrow D) of the bus bar portion 19, thereby forming a first adhesive layer 32a (S14a). The width, thickness, and viscosity of the first adhesive layer 32a are determined as appropriate such that, when connecting the wiring member 5 to the bus bar portion 19, the first adhesive layer 32a will not overflow from the outer peripheral portion of the wiring member 5 and will not be exposed on the light-receiving surface even when the first adhesive layer 32a is compressed by the wiring member 5. With respect to the width W1 of the wiring member 5 and the width W2 of the bus bar portion 19, the width W3 of the first adhesive layer 32a is preferably 0.4×W2 or greater and 0.47×W1 or smaller. If the width of the wiring member 5 is 1.5 mm and the width of the bus bar portion 19 is 1 mm, it is preferable that the width of the first adhesive layer 32a is 0.4 mm to 0.7 mm and the thickness of the first adhesive layer 32a is 10 μm to 100 μm. Further, the viscosity of the first adhesive layer 32a is preferably 20 Pa·s to 200 Pa·s. If a dispenser is used for applying the adhesive, the discharge pressure is preferably 0.1 MPa to 0.3 MPa.

Thereafter, as illustrated in FIG. 7, on the bus bar portion 19, an adhesive for the second adhesion section 34 is applied along the longitudinal direction of the bus bar portion 19 so as to sandwich the first adhesive layer 32a on both sides of the first adhesive layer 32a, thereby forming a second adhesive layer 34a (S14b). The width, thickness, and viscosity of the second adhesive layer 34a are determined as appropriate such that, when connecting the wiring member 5 to the bus bar portion 19, the second adhesive layer 34a serves as a barrier which prevents the first adhesive layer 32a from being exposed out of the outer peripheral portion of the wiring member 5 when the first adhesive layer 32a is compressed by the wiring member 5. With respect to the width W1 of the wiring member 5 and the width W2 of the bus bar portion 19, the width W4 of the second adhesive layer 34a is preferably 0.4×W2 or greater and 0.47×W1 or smaller. If the width of the wiring member 5 is 1.5 mm and the width of the bus bar portion 19 is 1 mm, it is preferable that the width of the second adhesive layer 34a is 0.4 mm to 0.7 mm and the thickness of the second adhesive layer 34a is 10 μm to 100 μm. Further, the viscosity of the second adhesive layer 34a is preferably 20 Pa·s to 200 Pa·s. In this example, it is assumed that the viscosity of the second adhesive layer 34a is higher than the viscosity of the first adhesive layer 32a. While it is possible to partially overlap the first adhesive layer 32a and the second adhesive layer 34a, an example in which they do not overlap will be described. Further, the first adhesive layer 32a and the second adhesive layer 34a may be formed by applying the adhesive by using separate individual nozzles or a single nozzle while switching the content within the nozzle.

Then, as illustrated in FIG. 8, the wiring member 5 is disposed at a position corresponding to the bus bar portion 19 (S14c). Finally, with thermal compression processing, the wiring member 5 is connected to the bus bar portion 19. It is preferable that, during the thermal compression step, the temperature condition, the pressure conditions, and other conditions that are necessary for connecting the wiring member 5 to the bus bar portion 19 firmly without a positional shift of the wiring member 5 with respect to the bus bar portion 19 are determined as appropriate. For example, it is preferable to apply a pressure of 0.05 MPa to 0.2 MPa for 5 to 20 seconds at a temperature of 200° C. With this processing, the first adhesive layer 32a is cured to form the first adhesion section 32 and the second adhesive layer 34a is cured to form the second adhesion section 34. With the first adhesion section 32 and the second adhesion section 34, the wiring member 5 is connected to the bus bar portion 19.

During the thermal compression step in S14d, the wiring member 5 is pressed to thereby compress the first adhesive layer 32a and the second adhesive layer 34a. Here, the first adhesive layer 32 is adjusted to have a preferable amount and viscosity such that the first adhesive layer 32a is not exposed from the other peripheral portion of the wiring member 5 even when compressed by the wiring member 5. Further, the first adhesive layer 32a is sandwiched by the second adhesive layer 34a provided on both sides thereof. With this configuration, the second adhesive layer 34a having a viscosity which is higher than the viscosity of the first adhesive layer 32a functions as a barrier which preferably prevents the first adhesive layer 32a from being exposed from the outer peripheral portion of the wiring member 5. Accordingly, in the photovoltaic module 1 after the thermal compression step in S14d, while a part of the second adhesion section 34 is exposed from the outer peripheral portion of the wiring member 5, the first adhesion section 32 is not exposed from the outer peripheral portion of the wiring member 5, as illustrated in FIG. 9.

While connection between the bus bar portion 22 on the rear surface side and the wiring member 5 may be similar to the connection between the bus bar portion 19 on the light-receiving surface side and the wiring member 5, the present invention is not limited to this example. For example, the connection between the bus bar portion 22 on the rear surface side and the wiring member 5 may be achieved only with the first adhesive layer 32a.

The operation of the photovoltaic module 1 having the structure described above will be described. In the photovoltaic module 1 according to the present embodiment, as illustrated in FIG. 9, the portion of the adhesion layer which is exposed from the outer peripheral portion of the wiring member 5 is the second adhesion section 34. Further, the second adhesion section 34 contains a smaller amount of conductive filler than in the first adhesion section 32, and is composed of a resin having a higher translucency than that of the first adhesion section 32. It is therefore possible to efficiently capture the sunlight and so on into the interior of the photovoltaic element 10. On the other hand, as the first adhesion section 32 is disposed so as to be covered with the wiring member 5 which blocks sunlight and so on, the first adhesion section 32 does not adversely affect blocking of sunlight. In addition, the first adhesion section 32 is composed of a resin having high conductivity which contains a greater amount of conductive filler than that of the second adhesion section 34, and has lower resistance than that of the second adhesion section 34. With this structure, it is possible to efficiently capture the sunlight and so on into the interior of the photovoltaic element 10 by the second adhesion section 34 and simultaneously enhance the collection efficiency in the wiring member 5 by compensating for the high resistance of the second adhesion section 34 by the first adhesion section 32. Consequently, the properties of the photovoltaic module 1 can be enhanced. Also, as the second adhesion section 34 can be provided so as to be exposed from the outer peripheral portion of the wiring member 5, it is possible to enhance the adhesive strength of the wiring member 5.

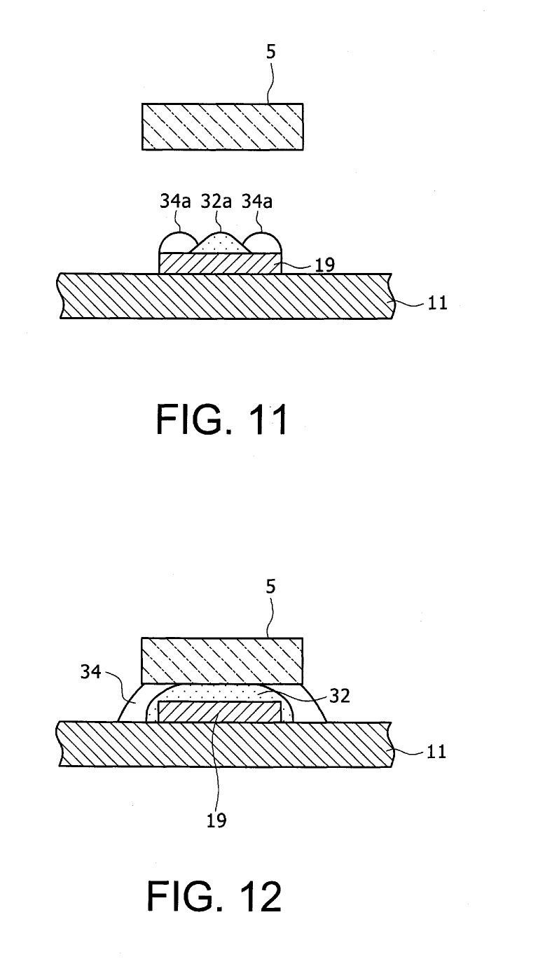

While, in the description of the manufacture of the photovoltaic module 1 configured as described above, the first adhesive layer 32a and the second adhesive layer 34a are not overlapped with each other, the first adhesive layer 32a and the second adhesive layer 34a may be partially overlapped with each other as illustrated in FIG. 11. Specifically, it is possible to form the first adhesive layer 32a into a mound and then form the second adhesive layer 34a on both sides of the first adhesive layer 32a so as to support the foot portions of the first adhesive layer 32a in a mound shape, as illustrated in FIG. 11. With this structure, as the foot portions of the first adhesive layer 32a are pressed and held by the second adhesive layer 34a at the time of connecting the wiring member 5 to the bus bar portion 19, it is possible to prevent the first adhesive layer 32a from overflowing from the wiring member 5 and being exposed. Consequently, as illustrated in FIG. 12, it is possible to allow the second adhesive layer 34a to overflow and be exposed from the outer peripheral portion of the wiring member 5, so that advantages similar to those achieved by the photovoltaic module 1 described above can be achieved.

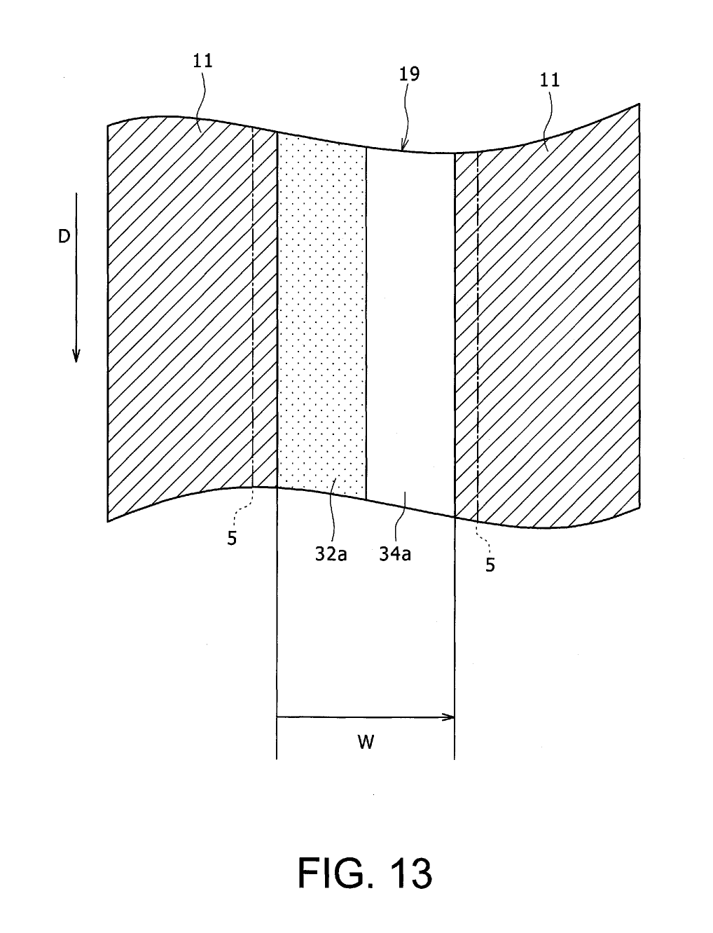

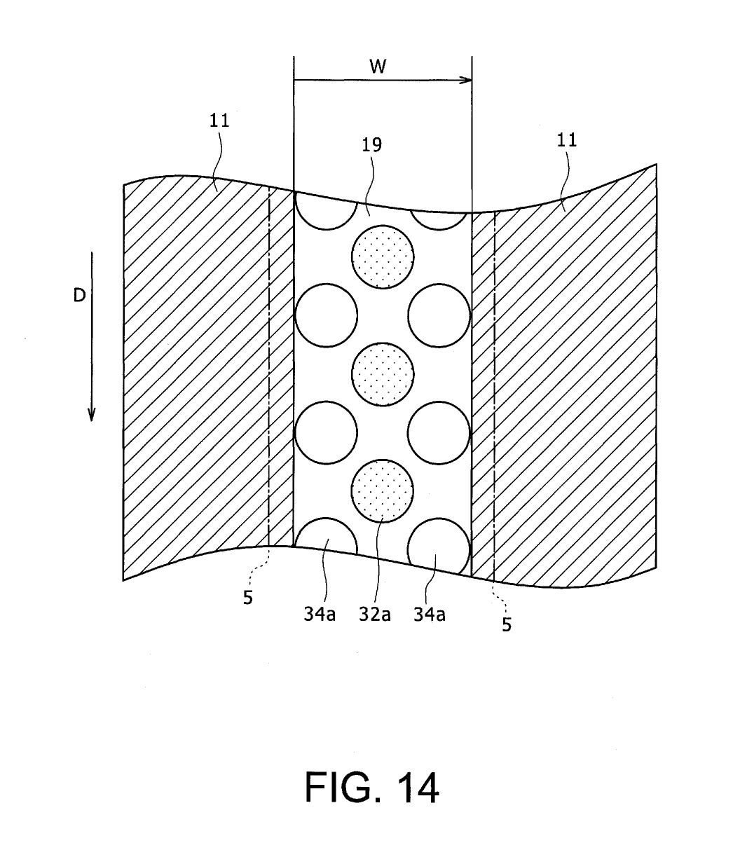

While, in the description of the photovoltaic module 1 having the structure as described above, the second adhesive layer 34a is provided on both sides of the first adhesive layer 32a, the present invention is not limited to such a positional relationship between the first adhesive layer 32 and the second adhesive layer 34a. For example, as illustrated in FIG. 13, it is possible to apply the first adhesive layer 32a along the longitudinal direction of the bus bar portion 19 in one half region in the width direction of the bus bar portion 19 (a left half region in the illustrated example) on the bus bar portion 19 and apply the second adhesive layer 34a along the longitudinal direction of the bus bar portion 19 in the other half region (a right half region in the illustrated example) on the bus bar portion 19. With this structure, it is similarly possible to maintain translucency by the second adhesion section 34 on at least one side of the bus bar portion 19 and simultaneously obtain collection efficiency by the first adhesion section 32.

Further, while in the description of the photovoltaic module 1 having the structure as described above the first adhesive layer 32a and the second adhesive layer 34a are formed by applying the adhesive in a line shape as illustrated in FIG. 7, the adhesive may be applied in a dot shape as illustrated in FIG. 14. Even when the adhesive is applied in a dot shape, as the first adhesive layer 32 is present in the center portion in the width direction of the bus bar portion 10 and the second adhesive layer 34 is present on both sides of the first adhesive layer 32, the advantages similar to those of the photovoltaic module 1 described above can be achieved.

While. in the description of the photovoltaic module 1 having the structure as described above, the first adhesion section 32 is not exposed from the wiring member 5, the advantages can be achieved to a certain degree if a part of the first adhesion section 32 is exposed. Specifically, as, even with this structure, at least a part of the adhesive exposed from the wiring member 5 is the second adhesion section 34, it is possible to capture the sunlight efficiently into the interior of the photovoltaic element 10 compared to the structure in which the whole adhesive layer 30 is composed solely of the first adhesion section 32.

In addition, while in the description of the photovoltaic module 1 having the structure as described above the second adhesive layer 34a is applied after the first adhesive layer is applied, the order of application is not limited to this example. Specifically, the first adhesive layer 32a and the second adhesive layer 34a may be applied simultaneously, or the first adhesive layer 32a may be applied after the second adhesive layer 34a is applied. As such, regardless of the order of application of the first adhesive layer 32a and the second adhesive layer 34a, the advantages similar to those of the photovoltaic module 1 described above can be achieved, as long as the second adhesion section 34 is exposed from the wiring member 5.

### REFERENCE SYMBOL LIST

1 photovoltaic module, 2 first protective member, 4 second protective member, 5 wiring member, 10 photovoltaic element, 11 transparent conductive layer, 12 n-type amorphous silicon layer, 13 i-type amorphous silicon layer, 14 n-type single-crystal silicon substrate, 15 i-type amorphous silicon layer, 16 p-type amorphous silicon layer, 17 transparent conductive layer, 19 bus bar portion, 20 finger portion, 21 collection electrode, 22 bus bar portion, 23 finger portion, 24 collection electrode, 30 adhesive layer, 32 first adhesion section, 32a first adhesive layer, 34 second adhesion section, 34a second adhesive layer.

1. A photovoltaic module comprising:
a photovoltaic element including an electrode (portion) on a light-receiving surface thereof;
a wiring member; and
an adhesive layer provided between the wiring member and the electrode portion, the adhesive layer including a first adhesion section and a second adhesion section,
the first adhesion section having conductivity that is higher than conductivity of the second adhesion section, and
the second adhesion section having translucency that is higher than translucency of the first adhesion section.

2. The photovoltaic module according to claim 1, wherein
the first adhesion section is provided along a longitudinal direction of the electrode portion, and
the second adhesion section is provided along the longitudinal direction on at least one side of the first adhesion section.

3. The photovoltaic module according to claim 1, wherein
the first adhesion section is provided such that the first adhesion section is not exposed from the wiring member.

4. The photovoltaic module according to claim 2, wherein
the first adhesion section is provided such that the first adhesion section is not exposed from the wiring member.

5. The photovoltaic module according to claim 1, wherein
the first adhesion section includes a resin containing a conductive filler, and
the second adhesion section includes a resin containing a conductive filler in a smaller amount than an amount of conductive filler in the first adhesion section.

6. The photovoltaic module according to claim 2, wherein
the first adhesion section includes a resin containing a conductive filler, and
the second adhesion section includes a resin containing a conductive filler in a smaller amount than an amount of conductive filler in the first adhesion section.

7. The photovoltaic module according to claim 3, wherein
the first adhesion section includes a resin containing a conductive filler, and
the second adhesion section includes a resin containing a conductive filler in a smaller amount than an amount of conductive filler in the first adhesion section.

8. The photovoltaic module according to claim 4, wherein
the first adhesion section includes a resin containing a conductive filler, and
the second adhesion section includes a resin containing a conductive filler in a smaller amount than an amount of conductive filler in the first adhesion section.
